(19) United States
(12) Patent Application Publication
(10) Pub. No.: US 2026/0123202 A1
(43) Pub. Date: Apr. 30, 2026

(54) Display Device

(71) Applicant: LG Display Co.,Ltd, Seoul (KR)

(72) Inventors: Jungcheol Shin, Paju-si (KR); YoungWook Lee, Paju-si (KR)

(21) Appl. No.: 19/210,348

(22) Filed: May 16, 2025

(30) Foreign Application Priority Data
Oct. 30, 2024 (KR) 10-2024-0150570

(51) Int. Cl. H10K 59/126; H10K 59/131; H10K 59/40; H10K 59/80

(52) U.S. Cl. CPC H10K 59/126; H10K 59/131; H10K 59/40; H10K 59/873

(57) ABSTRACT

A display device with improved moisture barrier properties is disclosed. The display device may include a display panel including an active area and a non-active area, a power line disposed in the non-active area, a plurality of metal layers extending from a portion of the power line and including a groove portion having a partially recessed side surface, and a shielding layer corresponding to the groove portion of the metal layers.

### CROSS REFERENCE TO RELATED APPLICATION

This application claims priority benefit from Republic of Korea Patent Application No. 10-2024-0150570, filed on Oct. 30, 2024, which is hereby incorporated by reference in its entirety.

### TECHNICAL FIELD

Embodiments of the present disclosure relate to an apparatus and particularly to, for example, without limitation, a display device.

### DESCRIPTION OF THE RELATED ART

With the advent of the information age, the display field, which visually presents electrical information signals, has rapidly advanced. In response, various types of display devices offering excellent performance in terms of thinness, light weight, and low power consumption have been developed.

Display devices for providing images to users—such as televisions, mobile phones, tablets, computers, navigation systems, and gaming consoles—may include a display panel that generates and displays images.

The display panel may include a plurality of pixels, a driving unit for driving the pixels, and signal lines for transmitting electrical signals to the pixels. The pixels, driving unit, and signal lines included in the display panel may be damaged or degraded by moisture or foreign substances introduced from the outside. Accordingly, research and development are needed to prevent damage and defects to the display panel caused by moisture or foreign substances.

### SUMMARY

Embodiments of the present disclosure may provide a display device with excellent moisture barrier properties by including a plurality of metal layers formed on a portion of a power line to increase a moisture permeation path.

Embodiments of the present disclosure may provide a display device that prevents or reduces cracks from forming in an inorganic material disposed on an upper portion of a metal layer, by including a shielding layer that covers a groove portion formed at a side of the metal layer.

Embodiments of the present disclosure may provide a display device with improved moisture barrier performance by including a plurality of inorganic layers covering the power line and the metal layers in a non-active area.

The objects addressed by the embodiments of the present disclosure are not limited to those mentioned above, and other objects not mentioned may be clearly understood by those skilled in the art from the following detailed description.

Embodiments of the present disclosure may provide a display device comprising: a display panel including an active area and a non-active area; a power line disposed in the non-active area; a plurality of metal layers extending from a portion of the power line and including a groove portion having a partially recessed side surface; and a shielding layer corresponding to the groove portion of the metal layers.

According to embodiments of the present disclosure, a display device with excellent moisture barrier properties may be provided by including a plurality of metal layers formed on a portion of a power line to increase a moisture permeation path.

According to embodiments of the present disclosure, a display device may be provided that prevents or reduces cracks in an inorganic material disposed on an upper portion of a metal layer by including a shielding layer covering a groove portion formed at a side of the metal layer.

According to embodiments of the present disclosure, a display device with improved moisture barrier performance may be provided by including a plurality of inorganic layers that cover the power line and the metal layers in a non-active area.

According to embodiments of the present disclosure, a display device capable of process optimization may be provided by forming the shielding layer using the same material as a bank layer, thereby allowing the bank layer and the shielding layer to be formed together.

The effects of the embodiments of the present disclosure are not limited to those described above, and additional effects not mentioned herein may be clearly understood by those skilled in the art from the claims.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE DRAWINGS

The present disclosure will be more fully understood from the following detailed description and the accompanying drawings. The detailed description and drawings are provided for illustrative purposes only and are not intended to limit the scope of the present specification.

FIG. 1 is a schematic diagram illustrating a configuration of a display device 100 according to embodiments of the present disclosure.

FIG. 2 is a schematic view illustrating a configuration of a display panel according to embodiments of the present disclosure.

FIG. 3 is a plan view of a display panel according to embodiments of the present disclosure.

FIG. 4 is a cross-sectional view taken along line A-A′ of FIG. 3 according to embodiments of the present disclosure.

FIG. 5 is an enlarged plan view of area “S” in FIG. 3 according to embodiments of the present disclosure.

FIG. 6 is a cross-sectional view taken along line B-B′ of FIG. 5 according to embodiments of the present disclosure.

FIG. 7 is a cross-sectional view of a metal layer according to one embodiment of the present disclosure.

FIG. 8 is a schematic view illustrating a shielding layer covering a groove portion of the metal layer shown in FIG. 7 according to embodiments of the present disclosure.

FIG. 9 is a cross-sectional view of a display panel according to another embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted or may be briefly discussed when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments may be provided so that this disclosure may be sufficiently thorough and complete to assist those skilled in the art to fully understand the scope of the present disclosure. Further, the present disclosure is only defined by scopes of claims.

Throughout the drawings and the detailed description, unless otherwise described, the same drawing reference numerals should be understood to refer to the same elements, features, and structures. The relative size and depiction of these elements may be exaggerated for clarity, illustration, and convenience. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

A shape, a size, a ratio, an angle, and a number disclosed in the drawings for describing embodiments of the present disclosure may be merely an example. Thus, the present disclosure is not limited to the illustrated details. Like reference numerals refer to like elements throughout. In the following description, when the detailed description of the relevant known function or configuration is determined to unnecessarily obscure an important point of the present disclosure, the detailed description of such known function or configuration may be omitted. When “comprise,” “have,” and “include” described in the present specification are used, another part may be added unless “only” is used. An element described in a singular form is intended to include a plurality of elements, and vice versa, unless the contrary context clearly indicates otherwise.

Any implementation described herein as an “example” is not necessarily to be construed as preferred or advantageous over other implementations.

In the description of the various embodiments of the present disclosure, where positional relationships are described, for example, when a position relation between two parts is described as, for example, “on,” “over,” “under,” and “next,” or the like, one or more other parts may be located between the two parts unless a more limiting term, such as “just” or “direct(ly)” is used. For example, where an element or layer is disposed “on” another element or layer, a third layer or element may be interposed therebetween.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by the scope of claims.

Features of various embodiments of the present disclosure may be partially or overall coupled to or combined with each other and may be variously inter-operated with each other and driven technically as those skilled in the art can sufficiently understand. Embodiments of the present disclosure may be carried out independently from each other or may be carried out together in co-dependent relationship.

Various embodiments of the present specification will be described in detail with reference to the accompanying drawings.

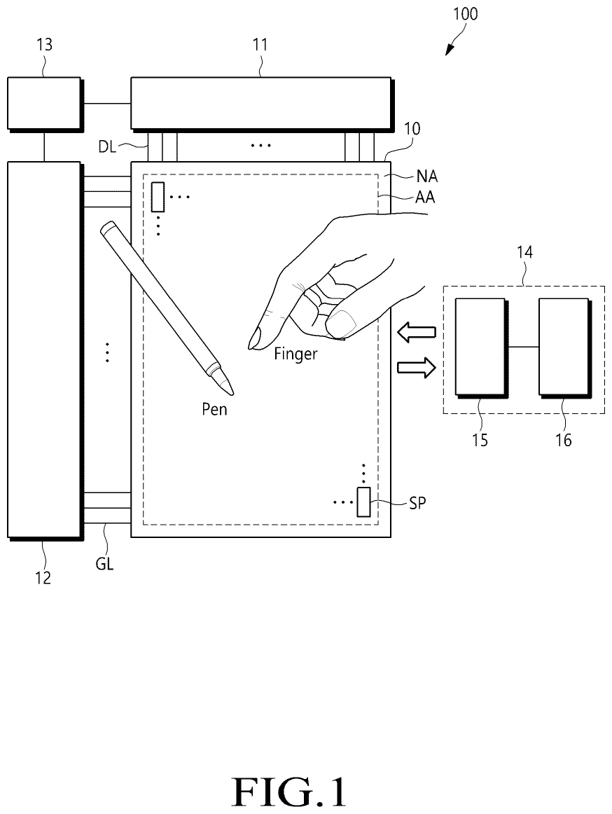

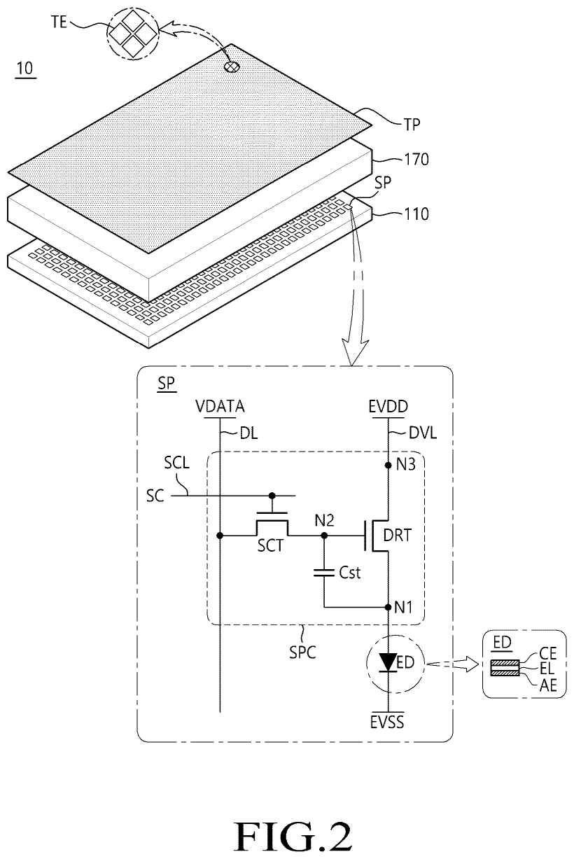

FIG. 1 is a schematic diagram illustrating a configuration of a display device according to embodiments of the present disclosure, and FIG. 2 is a diagram illustrating a configuration of a display panel according to embodiments of the present disclosure.

Referring to FIG. 1 and FIG. 2, the display device 100 may include a display panel 10 and a display driving circuit for driving the display panel 10, as components for displaying an image.

The display panel 10 may include an active area AA in which an image is displayed and a non-active area NA in which an image is not displayed. The non-active area NA may be an outer region of the active area AA and may correspond to a bezel region. All or a part of the non-active area NA may be visible on the front surface of the display device 100 or may be bent and thus not visible from the front surface of the display device 100.

The display panel 10 may include a plurality of sub-pixels SP. The display panel 10 may further include various types of signal lines to drive the plurality of sub-pixels SP. For example, the signal lines may include a plurality of data lines DL that deliver data signals (also referred to as data voltages or image signals) and a plurality of gate lines GL that deliver gate signals (also referred to as scan signals). However, embodiments of the present disclosure are not limited thereto.

The plurality of data lines DL and the plurality of gate lines GL may intersect each other. Each of the plurality of data lines DL may extend in a first direction, and each of the gate lines GL may be disposed, extending in a second direction. The first direction may correspond to a column direction and the second direction may correspond to a row direction, or vice versa.

The display device 100 according to embodiments of the present disclosure may be a liquid crystal display device, or a self-emissive display device in which the display panel 10 emits light by itself. In the case where the display device 100 is a self-emissive display device, each of the plurality of sub-pixels SP may include a light-emitting device ED and a pixel driving circuit SPC for driving the light-emitting device ED.

The pixel driving circuit SPC may include a driving transistor DRT, a scan transistor SCT, and a storage capacitor Cst.

The driving transistor DRT may control current flowing through the light-emitting device ED to drive the light-emitting device ED. The scan transistor SCT may deliver a data voltage VDATA to a second node N2, which is a gate node of the driving transistor DRT. The storage capacitor Cst may be configured to maintain a voltage for a predetermined period.

The light-emitting device ED may include a first electrode AE, a second electrode CE, and an emission layer EL disposed between the first and second electrodes. The first electrode AE may serve as a pixel electrode involved in the formation of the light-emitting device ED of each sub-pixel SP and may be electrically connected to a first node N1 of the driving transistor DRT. The second electrode CE may be a common electrode involved in the formation of the light-emitting device ED of all the sub-pixels SP and may receive a base voltage EVSS.

For example, the light-emitting device ED may be an organic light-emitting diode (OLED), an inorganic light-emitting diode (LED), or a quantum dot light-emitting device that includes semiconductor crystals emitting light by themselves. However, embodiments of the present disclosure are not limited thereto.

The driving transistor DRT, which drives the light-emitting device ED, may include a first node N1, a second node N2, and a third node N3. The first node N1 may be a source or drain node and may be electrically connected to the first electrode AE of the light-emitting device ED. The second node N2 may be a gate node and may be electrically connected to a source or drain node of the scan transistor SCT. The third node N3 may be a drain or source node and may be electrically connected to a driving voltage line DVL for supplying a driving voltage EVDD. For convenience of explanation, it is assumed that the first node N1 is a source node and the third node N3 is a drain node, although embodiments of the present disclosure are not limited thereto.

The scan transistor SCT may switch the connection between the data line DL and the second node N2 of the driving transistor DRT. The scan transistor SCT may control the connection between the second node N2 of the driving transistor DRT and a corresponding data line DL among the plurality of data lines DL in response to a scan signal SCAN supplied from a scan line SCL, which is a type of gate line GL. The storage capacitor Cst may be formed between the first node N1 and the second node N2 of the driving transistor DRT.

The structure of the sub-pixel SP illustrated in FIG. 2 is merely exemplary for explanatory purposes and may include one or more additional transistors or one or more additional capacitors. However, embodiments of the present disclosure are not limited thereto. The plurality of sub-pixels may all have the same structure, or some may have different structures. Each of the driving transistor DRT and the scan transistor SCT may be an n-type or p-type transistor. One of the driving transistor DRT and the scan transistor SCT may include one of an oxide semiconductor layer, a polysilicon semiconductor layer, or a low-temperature polysilicon semiconductor layer, but embodiments of the present disclosure are not limited thereto.

The display driving circuit may include a data driving circuit 11, a gate driving circuit 12, and a display controller 13.

The data driving circuit 11 may be a circuit for driving the plurality of data lines DL and may output data signals to the plurality of data lines DL. The gate driving circuit 12 may be a circuit for driving the plurality of gate lines GL and may output gate signals to the plurality of gate lines GL.

The display controller 13 may be a device such as a circuit for controlling the data driving circuit 11 and the gate driving circuit 12. The display controller 13 may control the driving timing of the plurality of data lines DL and the driving timing of the plurality of gate lines GL.

The display controller 13 may supply a data driving control signal to the data driving circuit 11 to control the data driving circuit 11 and may supply a gate driving control signal to the gate driving circuit 12 to control the gate driving circuit 12.

The data driving circuit 11 may supply data signals to the plurality of data lines DL based on driving timing control by the display controller 13. The data driving circuit 11 may receive image data in a digital format from the display controller 13, convert the received image data into analog data signals, and output the analog data signals to the plurality of data lines DL.

The gate driving circuit 12 may supply gate signals to the plurality of gate lines GL according to timing control by the display controller 13. The gate driving circuit 12 may receive various gate driving control signals (for example, a start signal, a reset signal, etc.) and supply a first gate voltage corresponding to a turn-on level and a second gate voltage corresponding to a turn-off level to generate gate signals, and output the generated gate signals to the plurality of gate lines GL.

The gate driving circuit 12 may be connected to the display panel 10 using a tape automated bonding (TAB) method, or may be connected to a bonding pad of the display panel 10 using a chip-on-glass (COG) method or a chip-on-panel (COP) method, or may be connected to the display panel 10 using a chip-on-film (COF) method. Alternatively, the gate driving circuit 12 may be formed in a non-active area NA of the display panel 10 as a gate-in-panel (GIP) type.

The gate driving circuit 12 may be disposed on or connected to a substrate, but embodiments of the present disclosure are not limited thereto. For example, when the gate driving circuit 12 is of the GIP type, it may be disposed in a non-active area NA of the substrate. When the gate driving circuit 12 is of the COG type or the COF type, it may be connected to the substrate.

At least one of the data driving circuit 11 and the gate driving circuit 12 may be disposed in the active area AA of the display panel 10. For example, at least one of the data driving circuit 11 and the gate driving circuit 12 may be disposed so as not to overlap the sub-pixels SP, or may be disposed so as to partially or entirely overlap the sub-pixels SP. However, embodiments of the present disclosure are not limited thereto.

The data driving circuit 11 may be connected to one side of the display panel 10 (for example, an upper side or a lower side). Depending on the driving method or panel design method, the data driving circuit 11 may be connected to both sides (for example, the upper side and the lower side) of the display panel 10 or may be connected to two or more sides among the four sides of the display panel 10. However, embodiments of the present disclosure are not limited thereto.

The gate driving circuit 12 may be connected to one side (for example, a left side or a right side) of the display panel 10. Depending on the driving method or panel design method, the gate driving circuit 12 may be connected to both sides (for example, the left side and the right side) of the display panel 10 or may be connected to two or more sides among the four sides of the display panel 10. However, embodiments of the present disclosure are not limited thereto.

The display controller 13 may be implemented as a separate component from the data driving circuit 11 or may be integrated with the data driving circuit 11 and implemented as an integrated circuit. However, embodiments of the present disclosure are not limited thereto.

The display controller 13 may be a timing controller used in conventional display technology, a controller that includes a timing controller and performs additional control functions, a controller different from a timing controller, or a circuit within a controller. The display controller 13 may be implemented using various circuits or electronic components such as an integrated circuit (IC), a field programmable gate array (FPGA), an application specific integrated circuit (ASIC), or a processor. However, embodiments of the present disclosure are not limited thereto.

The display controller 13 may be mounted on a printed circuit board or a flexible printed circuit and may be electrically connected to the data driving circuit 11 and the gate driving circuit 12 through the printed circuit board or flexible printed circuit.

The display controller 13 may transmit and receive signals to and from the data driving circuit 11 based on one or more predefined interfaces. For example, the interface may include a low voltage differential signaling (LVDS) interface, an EPI interface, or a serial peripheral interface (SPI), but embodiments of the present disclosure are not limited thereto.

The display device 100 according to embodiments of the present disclosure may include a touch panel TP and a touch sensing circuit 14 to provide a touch sensing function in addition to the image display function. The touch sensing circuit 14 may sense the touch panel TP to detect whether a touch has occurred by a touch object such as a finger or a pen, or to detect a touch position. The touch panel TP may be a touch part, but embodiments of the present disclosure are not limited thereto.

The touch panel TP may be a touch sensor and may include a plurality of touch electrodes TE. The touch panel TP may be disposed outside the display panel 10 or inside the display panel 10. When the touch panel TP is disposed outside the display panel 10, it is referred to as an external type. In this case, the touch panel TP and the display panel 10 may be separately manufactured and combined during assembly. When the touch panel TP is disposed inside the display panel 10, it is referred to as an embedded type. In this case, the touch panel TP may be formed inside the display panel 10 during a manufacturing process of the display panel 10. For example, the touch panel TP may be disposed on an encapsulation layer 170 within the display panel 10.

The touch sensing circuit 14 may include a touch driving circuit 15 that drives and senses the touch panel TP and generates and outputs touch sensing data, and a touch controller 16 that may detect a touch occurrence or a touch position using the touch sensing data.

The touch driving circuit 15 may supply a touch driving signal to at least one of the plurality of touch electrodes TE and may sense at least one of the plurality of touch electrodes TE to generate touch sensing data.

The touch sensing circuit 14 may perform touch sensing using a self-capacitance sensing method or a mutual-capacitance sensing method.

When the touch sensing circuit 14 performs touch sensing using the self-capacitance sensing method, the touch sensing circuit 14 may perform touch sensing based on capacitance between each touch electrode and a touch object (e.g., a finger or a pen).

According to the self-capacitance sensing method, each of the plurality of touch electrodes may serve both as a driving touch electrode and a sensing touch electrode. The touch driving circuit 15 may drive all or some of the plurality of touch electrodes and may also sense all or some of them.

When the touch sensing circuit 14 performs touch sensing using the mutual-capacitance sensing method, the touch sensing circuit 14 may perform touch sensing based on capacitance between touch electrodes.

According to the mutual-capacitance sensing method, the plurality of touch electrodes may include driving touch electrodes and sensing touch electrodes. The touch driving circuit 15 may drive the driving touch electrodes and sense the sensing touch electrodes.

The touch driving circuit 15 and the touch controller 17 included in the touch sensing circuit 14 may be implemented as separate devices or may be implemented as a single device. In addition, the touch driving circuit 15 and the data driving circuit 11 may be implemented as separate devices or as a single device.

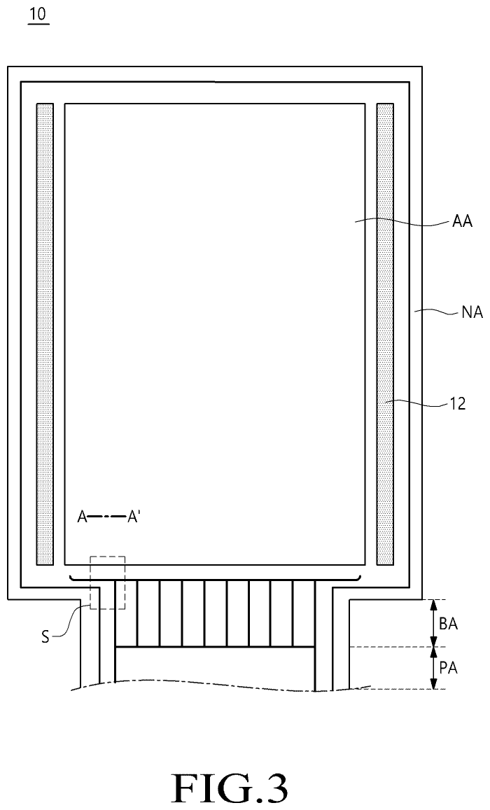

FIG. 3 is a plan view of a display panel according to embodiments of the present disclosure.

Referring to FIG. 3, the display panel 10 may include an active area AA and a non-active area NA.

The active area AA may display an image through a plurality of sub-pixels SP. The non-active area NA may be located around or surround the active area AA. The non-active area NA may include a bending area BA and a pad area PA. The bending area BA may be disposed at one side of the active area AA, and the pad area PA may be disposed at one side of the bending area BA. The bending area BA may be a region in which a base substrate 110 is bendable and may be located between the pad area PA and the active area AA.

The gate driving circuits 12 may be disposed on both sides of the active area AA. The gate driving circuit 12 may be of a gate-in-panel (GIP) type disposed inside the display panel 10. However, embodiments of the present disclosure are not limited thereto.

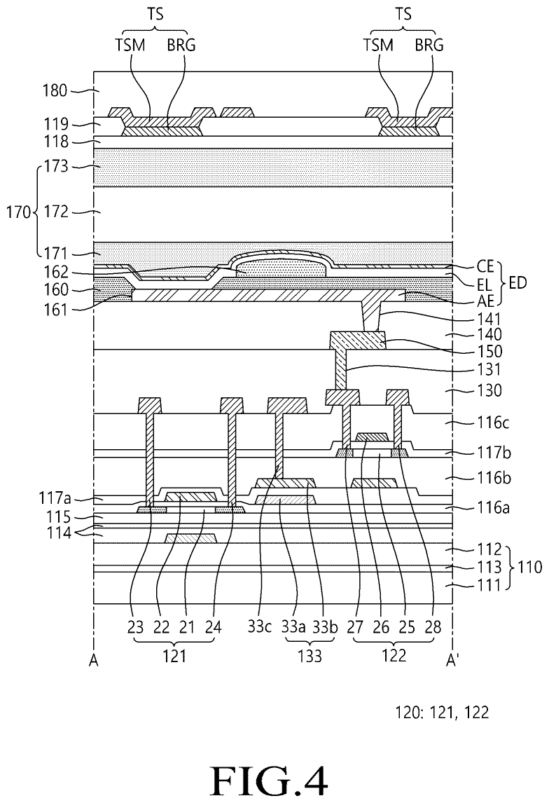

FIG. 4 is a cross-sectional view taken along line A-A′ of FIG. 3 according to one embodiment.

Referring to FIG. 4, the display panel 10 may include a base substrate 110, a thin-film transistor 120, a first planarization layer 130, a second planarization layer 140, a first electrode AE, a contact electrode 150, a bank layer 160, an emission layer EL, a second electrode CE, an encapsulation layer 170, and a protective layer 180.

The base substrate 110 serves to support various components of the display device 100 and may be formed of an insulating material such as a glass substrate or a plastic substrate.

The base substrate 110 may be disposed in the active area AA and the non-active area NA and may be composed of a plurality of layers. For example, the base substrate 110 may include a first base substrate 111, a second base substrate 112, and an insulating layer 113 disposed between the first base substrate 111 and the second base substrate 112.

The first base substrate 111 and the second base substrate 112 may be formed of polyimide (PI). Polyimide is a polymer that has relatively low crystallinity or mostly amorphous structure, is easy to synthesize into thin films, and has advantages in transparency, heat resistance, and mechanical properties. However, since polyimide has poor moisture barrier properties, the moisture barrier property of the base substrate 110 may be improved by disposing an insulating layer 113 made of an inorganic insulating material such as silicon nitride (SiNx) or silicon oxide (SiOx) between the first base substrate 111 and the second base substrate 112.

A plurality of buffer layers for blocking moisture and oxygen from entering may be disposed on the second base substrate 112. For example, the buffer layers may include a multi-buffer layer 114 and an active buffer layer 115.

The multi-buffer layer 114 serves to block moisture and oxygen from entering and may be formed of an inorganic material such as silicon nitride (SiNx), silicon oxide (SiOx), silicon oxynitride (SiON), or aluminum oxide (Al₂O₃). In this embodiment, the multi-buffer layer 114 is illustrated as including two layers, but it may include one layer or two or more two layers.

The active buffer layer 115 may be disposed on the multi-buffer layer 114 and may be formed of an inorganic material such as silicon nitride (SiNx), silicon oxide (SiOx), silicon oxynitride (SiON), or aluminum oxide (Al₂O₃).

The thin-film transistor 120 may be disposed on the base substrate 110 and may include a first thin-film transistor 121 and a second thin-film transistor 122.

The first thin-film transistor 121 may include a first semiconductor layer 21, a first gate electrode 22, a first source electrode 23, and a first drain electrode 24.

The first semiconductor layer 21 may be formed on the active buffer layer 115. The first semiconductor layer 21 may include a channel area, a source area, and a drain area. The channel area may be overlapped with the first gate electrode 22 through a first interlayer insulating layer 116a and may form a channel area between the first source electrode 23 and the first drain electrode 24. The source area may be electrically connected to the first source electrode 23, and the drain area may be electrically connected to the first drain electrode 24.

The first gate electrode 22 may be formed on the first interlayer insulating layer 116a. For example, the first gate electrode 22 may be overlapped with the channel area of the first semiconductor layer 21 through the first interlayer insulating layer 116a. The first gate electrode 22 may be formed of a single layer or multiple layers of any one or a combination of molybdenum (Mo), aluminum (Al), chromium (Cr), gold (Au), titanium (Ti), nickel (Ni), neodymium (Nd), and copper (Cu).

The first gate electrode 22 may be covered by a first gate insulating layer 117a, a second interlayer insulating layer 116b, a second gate insulating layer 117b, and a third interlayer insulating layer 116c.

The first source electrode 23 may penetrate through the first interlayer insulating layer 116a, the first gate insulating layer 117a, the second interlayer insulating layer 116b, the second gate insulating layer 117b, and the third interlayer insulating layer 116c, and may be connected to the source area of the first semiconductor layer 21.

The first drain electrode 24 may be disposed to face the first source electrode 23, and may penetrate through the first interlayer insulating layer 116a, the first gate insulating layer 117a, the second interlayer insulating layer 116b, the second gate insulating layer 117b, and the third interlayer insulating layer 116c, and may be connected to the drain area of the first semiconductor layer 21.

The second thin-film transistor 122 may be disposed to be spaced apart from the first thin-film transistor 121. The second thin-film transistor 122 may include a second semiconductor layer 25, a second gate electrode 26, a second source electrode 27, and a second drain electrode 28.

The second semiconductor layer 25 may be formed on the second interlayer insulating layer 116b. The second semiconductor layer 25 may include a channel area, a source area, and a drain area. The channel area may be overlapped with the second gate electrode 26 through the second gate insulating layer 117b and may form a channel area between the second source electrode 27 and the second drain electrode 28. The source area may be electrically connected to the second source electrode 27, and the drain area may be electrically connected to the second drain electrode 28.

The second gate electrode 26 may be formed on the second gate insulating layer 117b and may be covered by the third interlayer insulating layer 116c. For example, the second gate electrode 26 may overlap the channel area of the second semiconductor layer 25 with the first interlayer insulating layer 116a interposed therebetween. The second gate electrode 26 may be formed of a single layer or multiple layers of any one of molybdenum (Mo), aluminum (Al), chromium (Cr), gold (Au), titanium (Ti), nickel (Ni), neodymium (Nd), and copper (Cu), or an alloy thereof.

The second source electrode 27 may penetrate through the second gate insulating layer 117b and the third interlayer insulating layer 116c and be connected to the source area of the second semiconductor layer 25.

The second drain electrode 28 may be disposed to face the second source electrode 27 and may penetrate through the second gate insulating layer 117b and the third interlayer insulating layer 116c and be connected to the drain area of the second semiconductor layer 25.

In this embodiment, the first thin-film transistor 121 may be applied as the scan transistor SCT, and the second thin-film transistor 122 may be applied as the driving transistor DRT. However, the present disclosure is not limited to the illustrated example.

A storage capacitor 133 (Cst) may be disposed between the first thin-film transistor 121 and the second thin-film transistor 122.

The storage capacitor 133 may be configured such that a first storage electrode 33a and a second storage electrode 33b are overlapped with the first gate insulating layer 117a interposed therebetween.

The first storage electrode 33a may be electrically connected to either the second gate electrode 26 or the second source electrode 27 of the second thin-film transistor 122. For example, the first storage electrode 33a may be disposed on the first interlayer insulating layer 116a and may be formed in the same layer and of the same material as the first gate electrode 22.

The second storage electrode 33b may be disposed on the first gate insulating layer 117a and may be electrically connected to either the second gate electrode 26 or the second source electrode 27 of the second thin-film transistor 122 through a storage supply line 33c. For example, the storage supply line 33c may penetrate through the second interlayer insulating layer 116b, the second gate insulating layer 117b, and the third interlayer insulating layer 116c to be connected to the second storage electrode 33b.

The first planarization layer 130 may be disposed on the third interlayer insulating layer 116c formed on the base substrate 110 and may include a first contact hole 131 in an area overlapping the second source electrode 27. For example, the first planarization layer 130 may be formed of an organic material such as photo-acrylic (PAC) and may alleviate step differences caused by components of the first thin-film transistor 121, the second thin-film transistor 122, and the storage capacitor 133 disposed on the third interlayer insulating layer 116c.

The second planarization layer 140 may be disposed on the first planarization layer 130. For example, the second planarization layer 140 may be formed of an organic material such as photo-acrylic (PAC) and may include a second contact hole 141 in an area between the second source electrode 27 and the second drain electrode 28.

The first electrode AE may be disposed on the second planarization layer 140. In this embodiment, the first electrode AE may be an anode electrode.

The contact electrode 150 may be interposed between the first planarization layer 130 and the second planarization layer 140 and may electrically connect the thin-film transistor 120 and the first electrode AE. For example, the contact electrode 150 may be disposed on the first planarization layer 130 and may be electrically connected to the second source electrode 27 of the second thin-film transistor 122 through the first contact hole 131.

The bank layer 160 may be disposed on the second planarization layer 140 to partition pixels. For example, the bank layer 160 disposed in the active area AA may have an opening 161 exposing a portion of the first electrode AE located underneath.

The bank layer 160 may be formed of a material containing black pigment or may be composed of an organic material such as benzocyclobutene resin, polyimide resin, acrylic resin, or a photosensitive polymer. However, embodiments of the present disclosure are not limited thereto. When the bank layer 160 is formed of a material containing black pigment or black dye, it may be referred to as a black bank. Forming the bank layer 160 using a material containing black pigment or black dye may block light from the outside or reflected light, thereby further improving the luminance of the display device.

The bank layer 160 may include a spacer 162 for preventing or reducing damage caused by a mask used when forming the emission layer EL.

The emission layer EL may be disposed on the bank layer 160 and the first electrode AE. For example, the emission layer EL may be in contact with the first electrode AE exposed through the opening 161 of the bank layer 160. In this embodiment, the emission layer EL may be an organic emission layer that includes an organic compound layer such as a hole injection layer (HIL), a hole transport layer (HTL), an emission material layer (EML), an electron transfer layer (ETL), and an electron injection layer (EIL), but the present disclosure is not limited thereto.

The second electrode CE may be disposed on the emission layer EL. In this embodiment, the second electrode CE may be a cathode electrode.

The encapsulation layer 170 may be disposed on the second electrode CE. For example, the encapsulation layer 170 may cover the second electrode CE to protect the light-emitting device ED from external moisture, oxygen, impact, and the like.

The encapsulation layer 170 may include a first encapsulation layer 171, a second encapsulation layer 172, and a third encapsulation layer 173.

The first encapsulation layer 171 may be disposed on the second electrode CE and may be formed of an inorganic material capable of being deposited at a low temperature, such as silicon nitride (SiNx), silicon oxide (SiOx), silicon oxynitride (SiON), or aluminum oxide (Al₂O₃). When the first encapsulation layer 171 is deposited under a low-temperature atmosphere, it may prevent or reduce damage to the emission layer EL containing organic material, which may be vulnerable to high-temperature conditions during the deposition process.

The second encapsulation layer 172 may be disposed on the first encapsulation layer 171. For example, the second encapsulation layer 172 may be formed of an organic insulating material such as acrylic resin, epoxy resin, polyimide, polyethylene, or silicon oxycarbide (SiOC). Since the second encapsulation layer 172 is formed of an organic material, it may simultaneously seal the underlying components and alleviate step differences.

The third encapsulation layer 173 may be disposed on the second encapsulation layer 172. For example, the third encapsulation layer 173 may be formed of an inorganic material such as silicon nitride (SiNx), silicon oxide (SiOx), silicon oxynitride (SiON), or aluminum oxide (Al₂O₃).

As described above, since the encapsulation layer 170 is composed of multiple layers, it may effectively protect the light-emitting device ED by minimizing or at least reducing the penetration of moisture and oxygen from the outside.

According to this embodiment, a touch portion TS may be disposed on the encapsulation layer 170. For insulation and fabrication of the touch portion TS, a touch buffer layer 118 and a touch insulating layer 119, both formed of inorganic materials, may be disposed on the encapsulation layer 170.

The touch buffer layer 118 may be disposed on the encapsulation layer 170. A touch portion TS including a touch metal TSM and a bridge metal BRG may be disposed on the touch buffer layer 118. A touch insulating layer 119 may be disposed on the touch buffer layer 118, and the touch metal TSM and the bridge metal BRG may be brought into contact through an opening formed in the touch insulating layer 119.

The touch portion TS may be covered by a protective layer 180 disposed on the touch insulating layer 119. Accordingly, the protective layer 180 may cover the components and patterns disposed underneath and may reduce height differences due to the structure. For example, the protective layer 180 may be formed of an organic material such as acrylic resin, epoxy resin, phenolic resin, polyamide resin, or polyimide resin. However, the material of the protective layer 180 is not limited thereto, and the protective layer may also be formed of at least one inorganic material and at least one organic material. Embodiments of the present disclosure are not limited thereto.

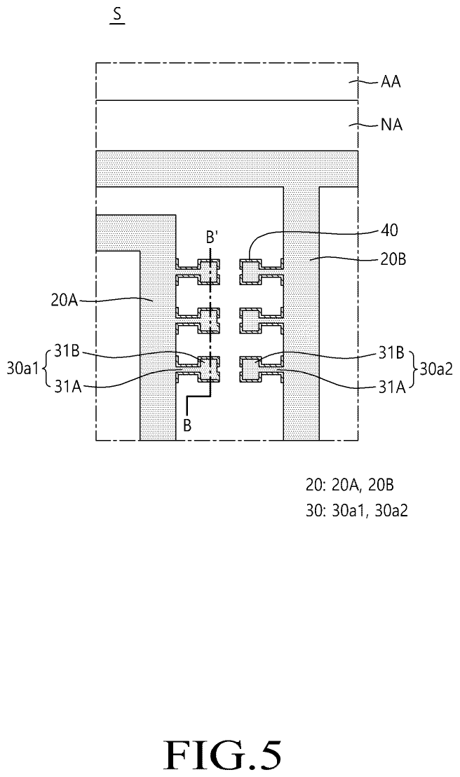

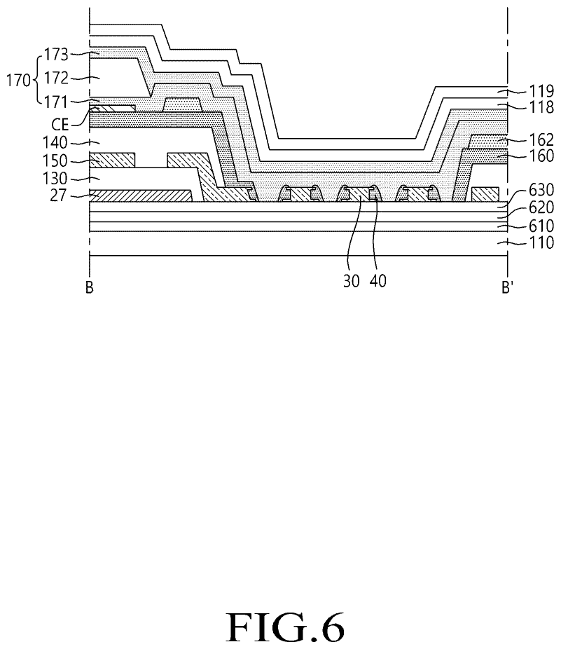

FIG. 5 is an enlarged plan view of the region “S” of FIG. 3 according to one embodiment and FIG. 6 is a cross-sectional view taken along line B-B′ of FIG. 5 according to one embodiment.

Referring to FIG. 5 and FIG. 6, the display device 100 may include a display panel 10, a power line 20, a metal layer 30, and a shielding layer 40.

The display panel 10 may include an active area AA and a non-active area NA. The display panel 10 may include a plurality of inorganic layers 610, 620, and 630 on a base substrate 110. Here, the inorganic layers 610, 620, and 630 may correspond to all or some of the layers 114 to 116c in FIG. 3 and FIG. 4. Other configurations of the display panel 10 are the same as those described in the previous embodiments and will not be described again in detail.

The power line 20 may be disposed in the non-active area NA and may include a first power line 20A and a second power line 20B. For example, the first power line 20A may include one of a common power line (VSS) and a driving current line (VDD), and the second power line 20B may include the other one of the common power line (VSS) and the driving current line (VDD).

In this embodiment, for convenience of explanation, it is assumed that the first power line 20A includes the common power line VSS, and the second power line 20B includes the driving current line VDD.

The first power line 20A may be used to supply a low-potential voltage to the second electrode CE, and a portion thereof may be disposed in a non-active area NA formed below the active area AA.

The second power line 20B may be used to supply a high-potential voltage, higher than the low-potential voltage, to a driving voltage line DVL, and a portion thereof may be disposed in the non-active area NA alongside the first power line 20A. That is, the first power line 20A and the second power line 20B may be disposed to face each other in a spaced-apart manner.

The metal layer 30 may be disposed in the non-active area NA to lengthen the path through which moisture may enter along the power line 20. For example, the metal layer 30 may be disposed in the non-active area NA between the active area AA and the bending area BA. In this embodiment, three metal layers 30 are illustrated, but the number is not limited thereto and may be greater. As the number of metal layers 30 increases, the moisture permeation path of the power line 20 may become longer.

The metal layer 30 may be formed of the same material as the contact electrode 150 and may be provided as a plurality of structures extending from a portion of a side surface of the power line 20. For example, a plurality of metal layers 30 extending from a side of the power line 20 may be disposed spaced apart from each other at regular intervals. As such, by providing the metal layer 30 on the power line 20, the moisture permeation path of the power line 20 may be increased, thereby improving the moisture barrier properties.

The metal layer 30 may include a first metal layer 30a1 and a second metal layer 30a2.

The first metal layer 30al may extend from a portion of the first power line 20A, and the second metal layer 30a2 may extend from a portion of the second power line 20B. For example, the first power line 20A and the second power line 20B may be disposed to face each other in a spaced-apart manner, and the first metal layer 30a1 may protrude toward the second power line 20B from one side of the first power line 20A, and the second metal layer 30a2 may protrude toward the first power line 20A from one side of the second power line 20B.

The metal layer 30 may include a protrusion 31A and a head portion 31B.

The protrusion 31A may extend from a portion of the power line 20, and a plurality of protrusions 31A may be disposed spaced apart from each other.

The head portion 31B may extend from an end of each of the protrusions 31A and may be formed to have a width greater than that of the protrusion 31A. As such, both side surfaces of the metal layer 30 may be recessed, and the length of the metal layer 30 may be increased according to the recessed length of the protrusion 31A. Accordingly, the moisture permeation path may be lengthened, and the moisture barrier performance of the display device 100 may be improved.

The shielding layer 40 may be disposed to correspond to the groove portion 30a. That is, the shielding layer 40 may cover the groove portion 30a formed at a side of the metal layer 30 to planarize a step 30b formed at the side of the metal layer 30. For example, the shielding layer 40 may be formed of the same material as the bank layer 160 or the second planarization layer 140. Accordingly, the shielding layer 40 may be formed together with the bank layer 160 or the second planarization layer 140, thereby simplifying the manufacturing process.

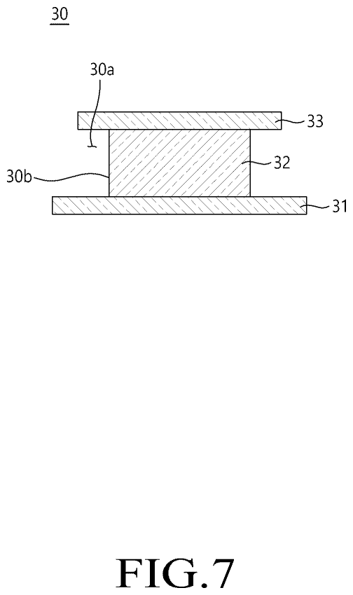

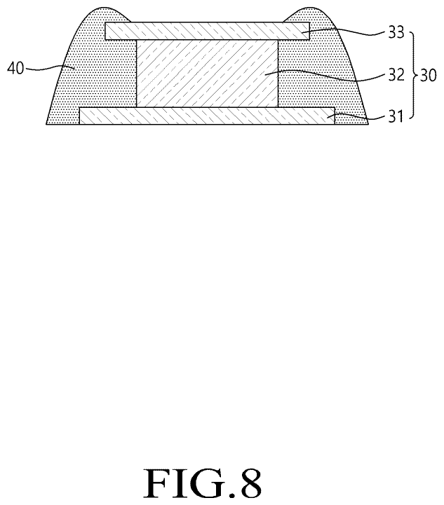

FIG. 7 is a cross-sectional view of a metal layer according to one embodiment of the present disclosure and FIG. 8 illustrates a shielding layer covering the groove portion of the metal layer shown in FIG. 7 according to one embodiment of the present disclosure.

Referring to FIG. 7 and FIG. 8, the metal layer 30 may include a plurality of layers. For example, the metal layer 30 may include a first layer 31, a second layer 32, and a third layer 33.

The first layer 31 may be formed of titanium (Ti). The second layer 32 may be disposed on the first layer 31 and may be formed of aluminum (Al). The third layer 33 may be disposed on the second layer 32 and may be formed of titanium (Ti). Since only the second layer 32 is formed of aluminum, a difference in etching rate between the titanium layers and the aluminum layer may result in the second layer 32 having a width smaller than those of the first and third layers. In other words, both sides of the second layer 32 may be undercut, forming the step 30b.

When the step 30b is formed at the side of the metal layer 30 as described above, cracks may occur in the first encapsulation layer 171 covering the metal layer 30 in the non-active area NA. If cracks occur in the first encapsulation layer 171, moisture may infiltrate along the power line 20 and cause defects in the display panel 10. To address this issue, the present embodiment may include the shielding layer 40 that covers the groove portion 30a of the metal layer 30 and planarizes the step 30b formed at the side of the metal layer 30.

For example, the shielding layer 40 may cover the side surfaces of the first layer 31, the second layer 32, and the third layer 33, and partially cover the upper surface of the third layer 33. That is, the shielding layer 40 may be disconnected on the upper portion of the third layer 33. This is because if the shielding layer 40 made of an organic material is continuously connected as a single body, it may become an additional moisture permeation path.

The groove portion 30a of the metal layer 30 may be planarized by the shielding layer 40. Accordingly, when the first encapsulation layer 171 is formed over the metal layer 30, the material of the first encapsulation layer 171 does not flow into the groove portion 30a of the metal layer 30, so cracks do not occur in the first encapsulation layer 171. Accordingly, the moisture barrier performance of the display panel 10 may be improved, and a display device 100 with excellent moisture resistance may be provided.

Meanwhile, the width of the third layer 33 may be greater than that of the second layer 32 and smaller than that of the first layer 31. Because of this structure, a portion of the groove portion 30a formed at the side of the second layer 32 may be exposed, allowing the shielding layer 40 to be more easily formed in the groove portion 30a.

According to the present embodiment, the power line 20 and the metal layer 30 may be covered by the first encapsulation layer 171, the third encapsulation layer 173, the touch buffer layer 118, and the touch insulating layer 119. That is, the first encapsulation layer 171, the third encapsulation layer 173, the touch buffer layer 118, and the touch insulating layer 119 may extend from the active area AA to the non-active area NA and cover the power line 20 and the metal layer 30.

As such, by covering the upper portion of the power line 20 and the metal layer 30 with the inorganic first encapsulation layer 171, third encapsulation layer 173, touch buffer layer 118, and touch insulating layer 119, the infiltration of moisture through the power line 20 and the metal layer 30 may be prevented or reduced, thereby further improving the moisture resistance of the display device 100.

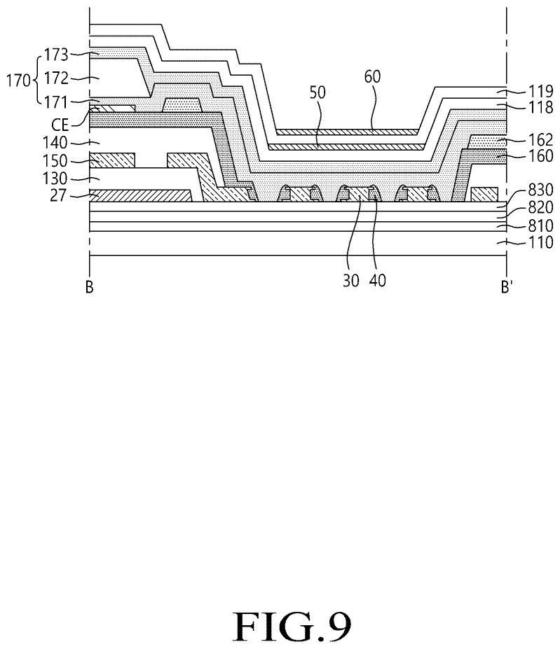

FIG. 9 is a cross-sectional view of a display panel according to another embodiment of the present disclosure. In this embodiment, the differences from the previous embodiments will be mainly described.

Referring to FIG. 9, the display device 100 may further include a first moisture barrier 50 and a second moisture barrier 60.

The first moisture barrier 50 may be disposed to overlap the metal layer 30 in the non-active area NA and may be interposed between the touch buffer layer 118 and the touch insulating layer 119. For example, the first moisture barrier 50 may be formed of the same material as the bridge metal BRG. By including the first moisture barrier 50 that covers the power line 20 and the metal layer 30 from above, moisture infiltration into the metal layer 30 may be effectively blocked, thereby improving the moisture barrier performance of the display device 100.

The second moisture barrier 60 may be disposed to overlap the metal layer 30 in the non-active area NA and may cover the touch insulating layer 119. For example, the second moisture barrier 60 may be formed of the same material as the touch metal TSM. By further including the second moisture barrier 60 that covers the upper portion of the metal layer 30, moisture infiltration into the metal layer 30 may be effectively blocked, thereby further improving the moisture barrier performance of the display device 100.

The embodiments of the present disclosure described above may be summarized as follows.

According to embodiments of the present disclosure, a display device may be provided that includes a display panel comprising an active area and a non-active area, a power line disposed in the non-active area, a plurality of metal layers extending from a portion of the power line and including a groove portion having a partially recessed side surface, and a shielding layer corresponding to the groove portion of the metal layers.

According to embodiments of the present disclosure, the non-active area may include a bending area disposed at one side of the active area, and the metal layers may be disposed in the non-active area between the active area and the bending area.

According to embodiments of the present disclosure, the metal layers may include a plurality of protrusions extending from a portion of the power line and spaced apart from each other, and a head portion extending from ends of the respective protrusions and having a width greater than that of the protrusions.

According to embodiments of the present disclosure, the metal layers may include a first layer, a second layer, and a third layer, where the first layer is formed of titanium (Ti), the second layer is disposed on the first layer and formed of aluminum (Al), the third layer is disposed on the second layer and formed of titanium (Ti), and the width of the second layer may be smaller than those of the first and third layers.

According to embodiments of the present disclosure, the width of the third layer may be greater than that of the second layer and smaller than that of the first layer.

According to embodiments of the present disclosure, the shielding layer may cover the side surfaces of the first, second, and third layers, and a portion of an upper surface of the third layer.

According to embodiments of the present disclosure, the display panel may include: a base substrate disposed in the active area and the non-active area; at least one thin-film transistor disposed on the base substrate; a first planarization layer covering the thin-film transistor; a second planarization layer disposed on the first planarization layer; a first electrode disposed on the second planarization layer; a contact electrode interposed between the first and second planarization layers and electrically connecting the thin-film transistor and the first electrode; a bank layer disposed on the second planarization layer and including an opening exposing a portion of the first electrode; an emission layer disposed on the bank layer and the first electrode; a second electrode disposed on the emission layer; and an encapsulation layer disposed on the second electrode.

According to embodiments of the present disclosure, the encapsulation layer may include a first encapsulation layer disposed on the second electrode, a second encapsulation layer disposed on the first encapsulation layer, and a third encapsulation layer disposed on the second encapsulation layer.

According to embodiments of the present disclosure, the first encapsulation layer and the third encapsulation layer may extend from the active area to the non-active area and may cover the power line and the metal layers.

According to embodiments of the present disclosure, the metal layers may be formed of the same material as the contact electrode.

According to embodiments of the present disclosure, the shielding layer may be formed of the same material as the bank layer or the second planarization layer.

According to embodiments of the present disclosure, a touch buffer layer disposed on the encapsulation layer and a touch insulating layer disposed on the touch buffer layer may further be included.

According to embodiments of the present disclosure, the touch buffer layer and the touch insulating layer may extend from the active area to the non-active area and may cover the power line and the metal layers.

According to embodiments of the present disclosure, the display device may further include a touch sensor portion disposed on the touch buffer layer and including a bridge metal and a touch metal disposed on the bridge metal.

According to embodiments of the present disclosure, a first moisture barrier may be disposed in the non-active area to overlap the metal layers and may be interposed between the touch buffer layer and the touch insulating layer.

According to embodiments of the present disclosure, the first moisture barrier may be formed of the same material as the bridge metal.

According to embodiments of the present disclosure, a second moisture barrier may be disposed in the non-active area to overlap the metal layers and may cover the touch insulating layer.

According to embodiments of the present disclosure, the second moisture barrier may be formed of the same material as the touch metal.

According to embodiments of the present disclosure, the power line may include a first power line and a second power line, and the metal layers may include a first metal layer formed on a portion of the first power line and a second metal layer formed on a portion of the second power line. The first power line having the first metal layer formed thereon and the second power line having the second metal layer formed thereon may be disposed to face each other in a spaced-apart manner.

According to embodiments of the present disclosure, the first power line may include one of a common power line and a driving current line, and the second power line may include the other of the common power line and the driving current line.

The above description has been presented to enable any person skilled in the art to make and use the technical idea of the present disclosure and has been provided in the context of a particular application and its requirements. Various modifications, additions and substitutions to the described embodiments will be readily apparent to those skilled in the art, and the general principles defined herein may be applied to other embodiments and applications without departing from the idea and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a display panel including an active area and a non-active area;
a power line in the non-active area;
a plurality of metal layers extending from a portion of the power line, the plurality of metal layers including a groove portion that has a partially recessed side surface; and
a shielding layer corresponding to the groove portion of the plurality of metal layers.

2. The display device according to claim 1, wherein the non-active area includes a bending area at one side of the active area and the plurality of metal layers are in the non-active area between the active area and the bending area.

3. The display device according to claim 1, wherein each of the plurality of metal layers comprises:
a plurality of protrusions extending from a portion of the power line, the plurality of protrusions spaced apart from each other; and
a head portion extending from an end of each of the plurality of protrusions, the head portion having a width that is greater than a width of the plurality of protrusions.

4. The display device according to claim 1, wherein each of the plurality of metal layers includes a first layer, a second layer, and a third layer,
wherein the first layer includes titanium,
the second layer is on the first layer and includes aluminum, and
the third layer is on the second layer and includes titanium,
wherein a width of the second layer is smaller than a width of the first layer and a width of the third layer.

5. The display device according to claim 4, wherein the width of the third layer is greater than the width of the second layer and the width of the third layer is smaller than the width of the first layer.

6. The display device according to claim 4, wherein the shielding layer covers side surfaces of the first layer, side surfaces of the second layer, and side surfaces of the third layer, and an upper portion of the third layer.

7. The display device according to claim 1, wherein the display panel comprises:
a base substrate in the active area and the non-active area;
at least one thin film transistor on the base substrate;
a first planarization layer covering the at least one thin film transistor,
a second planarization layer on the first planarization layer;
a first electrode on the second planarization layer;
a contact electrode between the first planarization layer and the second planarization layer, the contact electrode electrically connecting the at least one thin film transistor and the first electrode;
a bank layer on the second planarization layer, the bank layer having an opening that exposes a portion of the first electrode;
an emission layer on the bank layer and the first electrode;
a second electrode on the emission layer, and
an encapsulation layer on the second electrode.

8. The display device according to claim 7, wherein the encapsulation layer comprises a first encapsulation layer on the second electrode, a second encapsulation layer on the first encapsulation layer, and a third encapsulation layer on the second encapsulation layer.

9. The display device according to claim 8, wherein the first encapsulation layer and the third encapsulation layer extend from the active area to the non-active area and the first encapsulation layer and the third encapsulation layer cover the power line and the plurality of metal layers.

10. The display device according to claim 7, wherein the plurality of metal layers include a same material as the contact electrode.

11. The display device according to claim 7, wherein the shielding layer includes a same material as the bank layer or the second planarization layer.

12. The display device according to claim 7, further comprising:
a touch buffer layer and a touch insulating layer, the touch buffer layer on the encapsulation layer and the touch insulating layer on the touch buffer layer.

13. The display device according to claim 12, wherein the touch buffer layer and the touch insulating layer extend from the active area to the non-active area and the touch buffer layer and the touch insulating layer cover the power line and the plurality of metal layers.

14. The display device according to claim 12, further comprising:
a touch sensor portion on the touch buffer layer, the touch sensor portion including a bridge metal and a touch metal on the bridge metal.

15. The display device according to claim 14, further comprising:
a first moisture barrier in the non-active area and overlapping the plurality of metal layers, the first moisture barrier interposed between the touch buffer layer and the touch insulating layer.

16. The display device according to claim 15, wherein the first moisture barrier includes a same material as the bridge metal.

17. The display device according to claim 15, further comprising:
a second moisture barrier in the non-active area and overlapping the plurality of metal layers, the second moisture barrier covering the touch insulating layer.

18. The display device according to claim 17, wherein the second moisture barrier includes a same material as the touch metal.

19. The display device according to claim 1, wherein the power line includes a first power line and a second power line,
wherein the plurality of metal layers include a first metal layer on a portion of the first power line and a second metal layer on a portion of the second power line, and
wherein the portion of the first power line and the portion of the second power line face each other in a spaced-apart manner.

20. The display device according to claim 19, wherein the first power line includes one of a common power line and a driving current line and the second power line includes another one of the common power line and the driving current line.
